(19) United States
(12) Patent Application Publication
(10) Pub. No.: US 2011/0065277 A1
(43) Pub. Date: Mar. 17, 2011

(54) REFLOW METHOD, PATTERN GENERATING METHOD, AND FABRICATION METHOD FOR TFT FOR LCD

(75) Inventor: Yutaka ASOU, Kikuchi-gun (JP)

(73) Assignee: Tokyo Electron Limited, Tokyo (JP)

(21) Appl. No.: 12/947,477

(22) Filed: Nov. 16, 2010

Related U.S. Application Data
(62) Division of application No. 11/727,745, filed on Mar. 28, 2007.

(30) Foreign Application Priority Data
Mar. 31, 2006 (JP) 2006-098972

(51) Int. Cl. H01L 21/3213

(52) U.S. Cl. 438/694; 257/E21.314

(57) ABSTRACT

A to-be-processed object including an underlying layer and a resist film giving a pattern allowing formation of an exposure region in which the underlying layer is exposed at an upper layer to the underlying layer and a coverage region in which the underlying layer is covered is prepared. A reflow method is provided which softens the resist film to be in a flowing state, resulting in a part of or all of the exposure region covered by it. The resist film has different regions in thickness of at least a thick region and a thin region relatively thinner than the thick region.

### BACKGROUND OF THE INVENTION

1. Field of the Invention

The present invention relates to a resist reflow process in a pattern formation phase for semiconductor devices such as thin-film transistors (TFTs), a pattern formation method using the reflow process, and a method of fabricating a TFT for an LCD using the same.

2. Description of the Related Art

In recent years, semiconductor devices have been further highly integrated and miniaturized. However, the more integration and miniaturization progress, the more complex the semiconductor fabrication process becomes, resulting in higher fabrication cost. Accordingly, consolidating multiple mask-pattern fabrication processes using photolithography is considered, thereby reducing the total number of such processes in order to considerably lower the fabrication cost.

A reflow process allowing omission of some mask-pattern fabrication processes by soaking the resist with an organic solvent to soften the resist and thereby changing the shape of the initial resist pattern is proposed (e.g., see Japanese Patent Application Laid-open No. 2002-334830).

However, the method disclosed in Japanese Patent Application Laid-open No. 2002-334830 has a problem that it is difficult to control the coverage area and the orientation for softening and spreading the initial resist. The fourth embodiment of the above-mentioned Japanese Patent Application Laid-open No. 2002-334830, for example, discloses a technique that ref lows a resist mask having differing thicknesses to cover the channel regions of TFTs; wherein as shown in FIG. 1A, for example, while resists 507a and 507b having differing thicknesses are used as masks for the previous etching process, they are formed having the area as an ohmic contact layer 505 and source/drain electrode 506, which are underlying layers, thereupon.

Therefore, as shown in FIG. 1B, the modified ref lowed resist 511 after completion of the reflow process goes beyond the area of the ohmic contact layer 505 and the source/drain electrode 506, further extending onto an underlying a−Si layer 504. In other words, since it extends up to peripheral regions Z1 enclosed by dotted lines in FIG. 1B as well as the target region (i.e., channel region 510) for the reflow process, the area (dot area) necessary for fabrication of a single TFT, for example, becomes larger, resulting in difficulty in further improving integrity and miniaturization. Note that reference numeral 503 denotes an insulating film made of a silicon nitride, for example, and reference numeral 510 denotes a channel region, however the gate electrode thereof is omitted for convenience in FIGS. 1A and 1B (the same holds true for FIGS. 2A to 2C).

According to the fifth embodiment in the above-mentioned Japanese Patent Application Laid-open No. 2002-334830, a technique of performing an ashing process using O₂ plasma before resists 507 and 507b having respective differing thicknesses are subjected to a reflow process as shown in FIG. 2A has been proposed as shown in FIG. 2A. As shown in FIG. 2B, the thin region of the resist mask is removed through the O₂ plasma ashing process, reducing the coverage areas of the resists 508a and 508b, which are left adjacent to the channel region 510. Afterwards, the reflow process is performed. However, when the O₂ plasma ashing process is performed, the resist is generally also removed along the width, resulting in formation of steps D between the ends of the underlying layer (source and drain electrodes 506) and the sides of the resists 508a and 508b facing the channel region 510. The steps D cause the softened resist to take a longer time to go over the steps D than flat surfaces, and flow of the resist then stops. Consequently, it is difficult to control the flow orientation.

Even in the case of the flow of the softened resist stopping at the steps D, the flow progresses in a direction without steps. As a result, an incomplete coverage area by the deformed resist is formed, and at its worst, the deformed resist 511 may not cover the entirety of the channel region 510 as shown in FIG. 2C, and/or may cover a peripheral resist inflow prohibiting region Z₂, bringing about failure in device performance. Furthermore, the stoppage of the softened resist flow at the steps D may cause the reflow process to take longer, decreasing the TFT fabrication throughput.

As described above, according to the technique disclosed in Japanese Patent Application Laid-open No. 2002-334830, if the resist area before the reflow process and the underlying layer are corresponded, flow of the softened resist toward the peripheral regions cannot stop, making it difficult to miniaturize TFTs. On the other hand, if the resist area is reduced relative to that of the underlying layer, steps may develop in a desired spreading direction of the softened resist, stopping the flow (i.e., area extension) of the softened resist at the steps into the target regions, and the functionality thereof as a mask may thus be lost.

### SUMMARY OF THE INVENTION

An objective of the present invention is to provide a reflow method capable of controlling flow orientation and flow area of a softened resist.

Another objective of the present invention is to provide a pattern formation method applying such a reflow method.

Yet another objective of the present invention is to provide a fabrication method for a TFT for an LCD applying the reflow method.

According to a first aspect of the present invention, a reflow method, including: preparing a to-be-processed object, which includes an underlying layer and a resist film which has a pattern and which includes different regions in thickness of at least a thick region and a thin region relatively thinner than the thick region, where said pattern allows formation of an exposure region of the underlying layer exposed on an upper layer than the underlying layer and a coverage region in which the underlying layer is covered; and covering a part of or all of the exposure region by softening and ref lowing the resist film.

In the above-given reflow method, the flow orientation of the softened resist may be controlled by arrangement of the thick region and the thin region, and the coverage area by the resist may also be controlled by the arrangement of the thick region and the thin region.

Furthermore, the thick region may be provided on a side where spreading of the softened resist should be promoted, and the thin region may be provided on a side where spreading of the resist should be controlled. Alternatively, the thin region maybe provided on a side where spreading of the softened resist should be promoted, and the thick region may be provided on a side where spreading of the resist should be controlled.

Deformation of the resist may be performed in an organic solvent atmosphere.

Furthermore, flow orientation of the softened resist may be controlled by a flat shape of the resist film, and a coverage area by the softened resist may be controlled by a flat shape of the resist film.

Further, a step may be formed between the resist mask and the exposure region.

Yet even further, the thick region and the thin region of the resist film may be formed through half-exposure processing using a half-tone mask and development processing thereafter.

According to a second aspect of the present invention, a pattern formation method includes: forming a resist film in an upper layer than a to-be-etched film of a to-be-processed object; patterning the resist film so as to form different regions of the resist film in thickness including at least a thick region and a thin region relatively thinner than the thick region; redeveloping the patterned resist film and reducing coverage area by the patterned resist film; softening the resist film to be in a reflowed state, and covering a target region of the to-be-etched film by the reflowed resist while controlling flow orientation and flow rate of the softened resist based on the locations of the thick region and the thin region; etching an exposed region of the to-be-etched film using the resist deformed by said reflowing as a mask; removing the resist; and etching a target region of the to-be-etched film re-exposed through removal of the resist.

In the above-given pattern formation method, the same method as the reflow method according to the first aspect may be employed when the resist film is subjected to reflowing.

Further in the aforementioned pattern formation method, a damaged layer on the resist surface may be removed before redeveloping of the patterned resist film.

Moreover, the to-be-processed body has a stacked structure in which a gate line and a gate electrode are formed on a substrate, a gate insulating film is formed to cover them, and an a−Si film, a Si film for ohmic contact, and a metallic film for source and drain are then formed on the gate insulating film in order from bottom up, and the to-be-etched film may be the Si film for ohmic contact.

In this case, a step may be formed between an end of the resist film on a side facing the target region and an end of the metallic film for source and drain in an underlayer thereto through the redeveloping.

According to a third aspect of the present invention, a fabrication method for a TFT for an LCD includes: forming a gate line and a gate electrode on a substrate; forming a gate insulating film that covers the gate line and the gate electrode; depositing an a−Si film, a Si film for ohmic contact, and a metallic film for source and drain on the gate insulating film in order from the bottom; forming a resist film on the metallic film for source and drain; forming a resist mask for a source electrode and a resist mask for a drain electrode through half-exposure processing and development processing, so as to form different regions of the resist film in thickness including at least a thick region and a thin region relatively thinner than the thick region; etching the metallic film for source and drain using the resist mask for a source electrode and the resist mask for a drain electrode as a mask, forming a metallic film for a source electrode and a metallic film for a drain electrode, and exposing a Si film for ohmic contact in an underlying layer to a concave region for a channel region between the metallic film for the source electrode and a metallic film for the drain electrode; redeveloping the patterned resist mask for the source electrode and resist mask for the drain electrode, and reducing respective coverage areas by them with the thick region and the thin region left as they are; making an organic solvent act on the resist mask for the reduced source electrode and resist mask for the drain electrode to soften them to be in a reflowed state and deformed, and covering by the reflowed resist the Si film for ohmic contact within the concave region for the channel region between the metallic film for the source electrode and the metallic film for the drain electrode; etching the Si film for ohmic contact and the a−Si film in underlayers using the deformed resist resulting from reflowing, the metallic film for a source electrode, and the metallic film for a drain electrode as a mask; removing the resist and re-exposing the Si film for ohmic contact within the concave part for a channel region between the metallic film for a source electrode and the metallic film for a drain electrode; and etching the Si film for ohmic contact exposed to the concave part for a channel region between the metallic film for a source electrode and the metallic film for a drain electrode using the films as a mask.

In the above-given fabrication method for a TFT for an LCD, the same method as the reflow method according to the first aspect may be employed when the resist film is subjected to ref lowing.

Furthermore, the thick region may be formed in the concave part for the channel region between the metallic film for the source electrode and the metallic film for the drain electrode, and the thin region may be formed in the concave part for the channel region.

Moreover, distance between the resist mask for the source electrode and the resist mask for the drain electrode in the concave part for the channel region may be formed greater than distance between metallic film for the source electrode and the metallic film for the drain electrode in an underlayer thereto through the redeveloping.

According to a fourth aspect of the present invention, a storage medium, which is stored with a program for controlling a processing unit to be executed by a computer, is provided. The program is executed by the computer to control the processing unit, so as to implement a reflow method including: preparing a to-be-processed object, which includes an underlying layer and a resist film patterned so that an exposure region in which the underlying layer is exposed in an upper layer to the underlying layer and a coverage region in which the underlying layer is covered are formed, wherein the resist film has a shape comprising different regions in thickness, which include at least a thick region and a thin region relatively thinner than the thick region, and covering a part of or all of the exposure region by softening and ref lowing the resist film.

According to the present invention, use of a resist film having a thick region and a thin region for ref lowing controls flow orientation and flow area (spreading area) of softened resist.

### BRIEF DESCRIPTION OF THE DRAWINGS

FIGS. 1A and 1B are cross-sections explaining a conventional reflow method;

FIGS. 2A through 2C are cross-sections explaining the conventional reflow method;

FIG. 3 is a top view of an outline of a reflow processing system;

FIG. 4 is a top view of an outline of a redevelopment/remover unit;

FIG. 5 is a cross-section of a general structure of the redevelopment/remover unit;

FIG. 6 is a cross-section of a general structure of the reflow processing unit (REFLW);

FIGS. 7A through 7C show a principle of the conventional reflow method;

FIGS. 8A through 8C show a principle of a reflow method according to an embodiment of the present invention;

FIGS. 9A through 9C show a principle of a reflow method according to another embodiment of the present invention;

FIG. 10A is a graph explaining a relationship between the flow speed of a softened resist and thinner concentration;

FIG. 10B is a graph explaining a relationship between the flow speed of the softened resist and temperature;

FIG. 10C is a graph explaining a relationship between the flow speed of the softened resist and applied pressure;

FIG. 10D is a graph explaining a relationship between the flow speed of the softened resist and the thinner flow;

FIGS. 11 and 12 are references explaining a principle of a reflow method;

FIG. 13A shows a principle of a reflow method according to another embodiment of the present invention;

FIG. 13B is a cross-section of a resist shown in FIG. 13A;

FIG. 14 is a vertical cross-section of a substrate in which a gate electrode and a laminated film are formed on an insulating substrate in a TFT fabrication process;

FIG. 15 is a vertical cross-section of a substrate having a resist film formed thereupon in the TFT fabrication process ;

FIG. 16 is a vertical cross-section of the substrate being subjected to half-exposure processing in the TFT fabrication process;

FIG. 17 is a vertical cross-section of the substrate after the half-exposure processing is completed in the TFT fabrication process;

FIG. 18 is a vertical cross-section of the substrate after development in the TFT fabrication process;

FIG. 19 is a vertical cross-section of the substrate after a metallic film for electrodes in the TFT fabrication process ;

FIG. 20 is a vertical cross-section of the substrate after a preprocess and redevelopment in the TFT fabrication process;

FIG. 21 is a vertical cross-section of the substrate after a reflow process in the TFT fabrication process;

FIG. 22 is a vertical cross-section of the substrate after an n+Si film and an a−Si film are etched in the TFT fabrication process;

FIG. 23 is a vertical cross-section of the substrate after a deformed resist is removed in the TFT fabrication process ;

FIG. 24 is a vertical cross-section of the substrate having a channel region formed therein in the TFT fabrication process;

FIG. 25 is a top view of the substrate shown in FIG. 20;

FIG. 26 is a top view of the substrate shown in FIG. 21; and

FIG. 27 is a flowchart explaining the TFT fabrication process.

### DESCRIPTION OF THE PREFERRED EMBODIMENTS

Preferred embodiments according to the present invention are described forthwith while referencing the drawings.

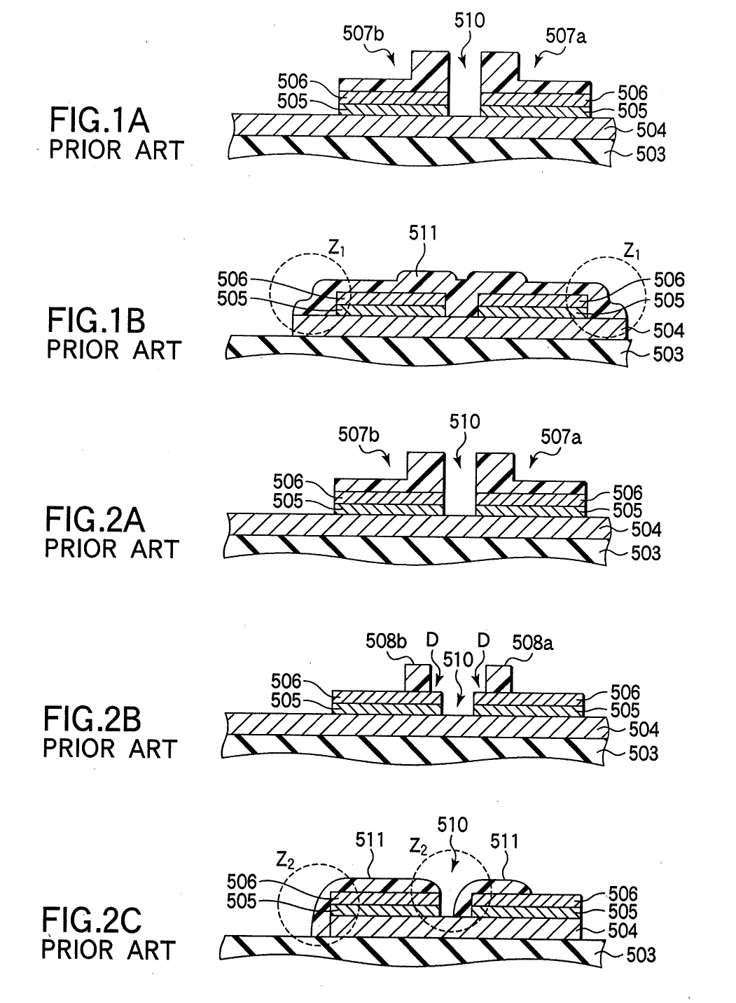

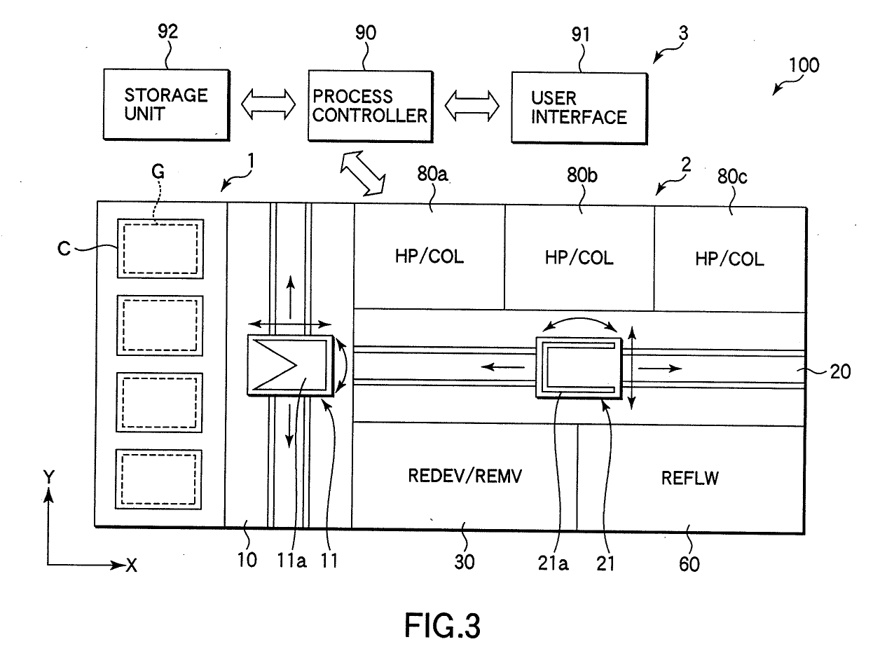

FIG. 3 is a top view of an entire reflow processing system available according to a reflow method of the present invention. Here, a reflow processing system including a reflow processing unit, which softens and deforms a resist film formed on an LCD glass substrate (hereafter simply called ‘substrate’) after development and then performs ref lowing tore-cover, and a redevelopment/remover unit (REDEV/REMV), which performs redevelopment and preprocessing before reflowing, is described as an example. This reflow processing system 100 includes a cassette station (carry-in/out unit) 1 in which each cassette C accommodating multiple substrates G is placed, a processing station (processing unit) 2, which includes multiple processing units for performing successive processing such as reflow processing and redevelopment processing for each substrate G, and a control unit 3, which controls each unit of the reflow processing system 100. Note that the direction along the length of the reflow processing system 100 is defined as X direction while direction perpendicular to the X direction on a plane is defined as Y direction in FIG. 1.

The cassette station 1 is deployed next to an end of the processing station 2. The cassette station 1 including a transfer unit 11, which carries in and out the substrates G between the cassette C and the processing station 2, and carries in and out the cassettes C from/to the outside. The transfer unit 11 has a transfer arm 11a movable along a transfer path 10 extending in the Y direction in which the cassettes C are aligned. This transfer arm 11a is provided capable of moving back and forth in the X direction, moving up and down, and rotating, allowing transfer of the substrates G between the cassette C and the processing station 2.

The processing station 2 includes multiple processing units, which perform successive processes for resist reflowing, preprocessing, and redevelopment processing for the substrates G. Each of these processing units processes the substrates G one by one. The processing station 2 also includes a central transfer path 20 for transferring the substrates G basically extending in the X direction. The processing units are deployed at both ends of this central transfer path 20, facing the central transfer path 20.

A transfer unit 21, which carries in and out the substrates G between each processing unit, is provided along the central transfer path 20 and has a transfer arm 21a movable in the X direction in which the processing units are deployed. This transfer arm 21a is provided capable of moving back and forth in the Y direction, moving up and down, and rotating, allowing transfer of the substrates G between each processing unit.

On one side along the central transfer path 20 of the processing station 2, a redevelopment/remover unit (REDEV/REMV) 30 and a reflow processing unit (REFLW) 60 are aligned in this order from the cassette station 1 side while at the other side along the central transfer path 20 of the processing station 2, three heating/cooling units (HP/COLs) 80a, 80b, and 80c are deployed in a line. Each of the heating/cooling units (HP/COLs) 80a, 80b, and 80c is made up of multiple layers stacked vertically (omitted from the drawing).

The redevelopment/remover unit (REDEV/REMV) 30 is a processing unit, which performs preprocessing for removal of a damaged layer in a metal etching process or other related processes by another processing system not shown in the drawing and redevelopment processing for redevelopment of a resist pattern previous to ref lowing. This redevelopment/remover unit (REDEV/REMV) 30 includes a fluid spinning/processing unit, which has a redevelopment chemical discharge nozzle for redevelopment and a removal fluid discharge nozzle for preprocessing to discharge a treatment fluid onto a substrate G while holding and rotating the substrate G at a fixed speed to allow application of the processing liquid for redevelopment and preprocessing (i.e., removing the damaged layer on the resist surface).

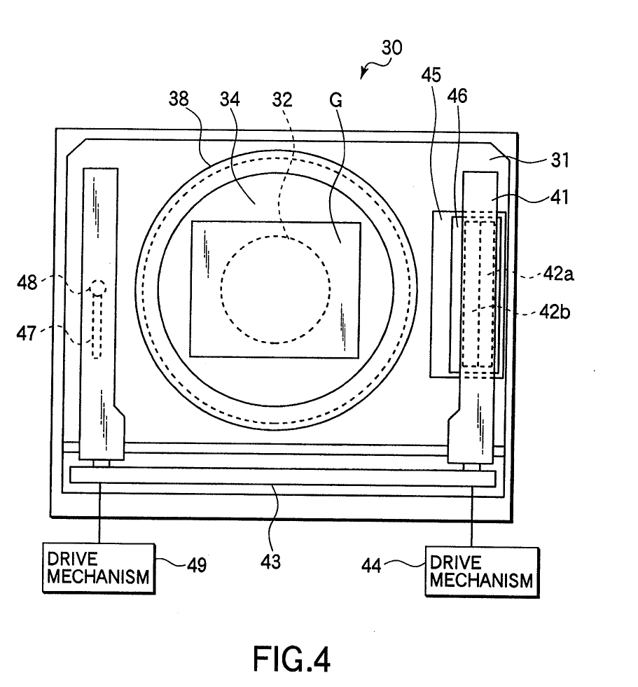

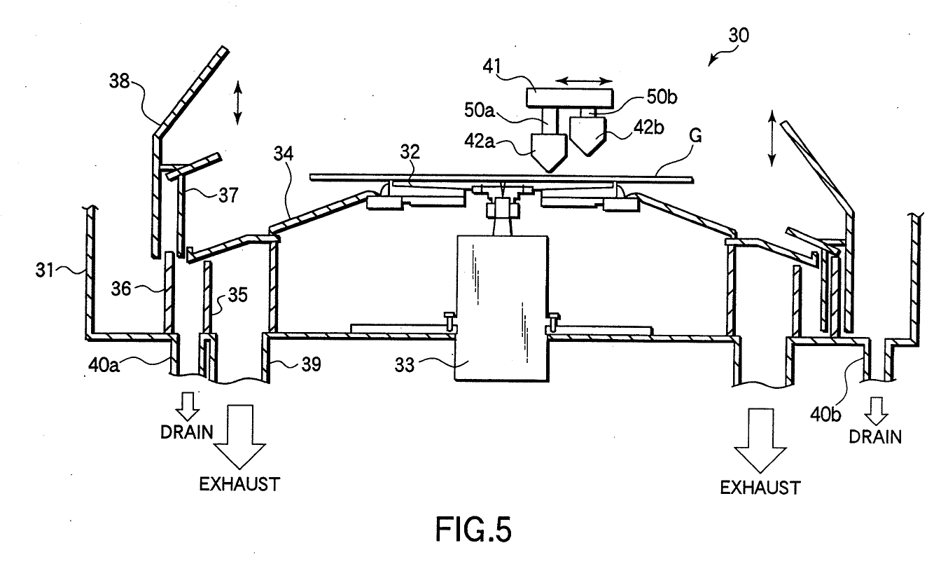

Now, the redevelopment/remover unit (REDEV/REMV) 30 is described while referencing FIGS. 4 and 5. FIG. 4 is a top view of the redevelopment/remover unit (REDEV/REMV) 30 while FIG. 5 is a cross-section of a cup of the redevelopment/remover unit (REDEV/REMV) 30. As shown in FIG. 2, the entirety of the redevelopment/remover unit (REDEV/REMV) 30 is enclosed by a sink 31. As shown in FIG. 3, the redevelopment/remover unit (REDEV/REMV) 30 has a holding means such as a spin chuck 32, which holds a substrate G mechanically and is rotated by a rotation driving mechanism 33 such as a motor. A cover 34 enclosing the rotation driving mechanism 33 is deployed under this spin chuck 32. The spin chuck 32 is capable of moving up and down under the control of a lifting mechanism not shown in the drawing, transferring the substrate G from/to the transfer arm 21a at a lifting position. This spin chuck 32 is capable of adsorptive retention of the substrate G using vacuum attracting force or other forces.

Two undercups 35 and 36 are deployed on the periphery of a cover 34 at a distance from each other. Above the two undercups 35 and 36, an innercup 37, which mainly passes a redevelopment chemical downwards, is provided to freely move up and down. At the outside of the undercup 36, an outercup 38, which mainly passes a rinsing fluid downwards, is integrally provided capable of moving up and down in conjunction with the innercup 37. Note that rising positions of the innercup 37 and the outercup 38 when the redevelopment chemical is being discharged are shown on the left side of FIG. 5, and lowering positions thereof when the rinsing fluid is being discharged are shown on the right side.

An exhaust outlet 39 is provided on the inner bottom of the undercup 35 to evacuate the unit when spinning and drying. A drain pipe 40a is deployed between the two undercups 35 and 36 to mainly drain the redevelopment chemical, and a drain pipe 40b is deployed on the outer bottom of the undercup 36 to mainly drain rinsing fluid.

As shown in FIG. 4, on one side of the outercup 38, a nozzle holding arm 41 for supplying the redevelopment chemical and removal fluid is deployed, wherein the nozzle holding arm 41 accommodates a redevelopment chemical discharge nozzle 42a for applying the redevelopment chemical 25, to substrate G and a removal fluid discharge nozzle 42b.

A nozzle holding arm 41 is structured movable along the length of a guide rail 43 across the substrate G under the control of a drive mechanism 44 for driving a belt and the like. For application of the redevelopment chemical and discharge of the removal fluid, the nozzle holding arm 41 scans a stationary substrate G while the redevelopment chemical discharge nozzle 42a is discharging the redevelopment chemical or the removal fluid discharge nozzle 42b is discharging the removal fluid.

The redevelopment chemical discharge nozzle 42a and the removal fluid discharge nozzle 42b can be retracted in a nozzle retraction region 45, which accommodates a nozzle cleaning mechanism 46 for cleaning the redevelopment chemical discharge nozzle 42a and the removal fluid discharge nozzle 42b.

On the other side of the outercup 38, a nozzle holding arm 47 for discharging a rinsing fluid such as pure water is deployed while a rinsing fluid discharge nozzle 48 is deployed at the edge of the nozzle holding arm 47. The rinsing fluid discharge nozzle 48 may have a pipe-shaped discharge opening, for example. The nozzle holding arm 47 is structured capable of sliding along the length of a guide rail 43 under the control of a drive mechanism 49 and scanning the substrate G while the rinsing fluid discharge nozzle 48 is discharging the rinsing fluid.

Next, an outline of preprocessing and redevelopment processing using the aforementioned redevelopment/remover unit (REDEV/REMV) 30 is described. First, the innercup 37 and the outercup 38 are positioned at a lower position (i.e., the position shown on the right side of FIG. 5), the transfer arm 21a holding a substrate G is inserted to the redevelopment/remover unit (REDEV/REMV) 30, the spin chuck 32 is lifted at the same timing, and the substrate G is then transferred into the spin chuck 32. Once the transfer arm 21a is retracted from the redevelopment/remover unit (REDEV/REMV) 30, the spin chuck 32 on which the substrate G is mounted is lowered and then kept at a predetermined position. Then, the nozzle holding arm 41 moves to and stays at the predetermined position in the innercup 37, a lifting mechanism 50b is extended to move and hold only the removal fluid discharge nozzle 42b at a lower position, and an alkaline removal fluid is discharged onto the substrate G using the removal fluid discharge nozzle 42b while the substrate G is scanned. A strong alkaline aqueous solution, for example, may be used as the removal fluid. During a predetermined reaction time, the lifting mechanism 50b contracts to return the removal fluid discharge nozzle 42b to an upper position and stay there, the nozzle holding arm 41 is retracted from the innercup 37 and the outercup 38, the nozzle holding arm 47 is then driven instead to move the rinsing fluid discharge nozzle 48 up to a predetermined position on the substrate G. Afterwards, the innercup 37 and the outercup 38 are lifted and then kept at the upper position (on the left side of FIG. 5).

The substrate G is then rotated at a low speed, and as the removal fluid on the substrate G is about to be shaken off, the rinsing fluid discharge nozzle 48 starts discharging the rinsing fluid. At almost the same time as this operation starts, an exhaust outlet 39 starts evacuating. The removal fluid and the rinsing fluid scattering towards the outer area of the substrate G after the substrate G starts rotating hit the tapered part of the innercup 37 and/or external wall (vertical side wall) and are then guided down to drain from the drain pipe 40a.

After a predetermined time has elapsed since the substrate G as started rotating, the innercup 37 and the outercup 38 are lowered and then kept at a lower position while discharging the rinsing fluid and also rotating the substrate G. At the lower position, the horizontal position of the substrate G is set to be almost the same as that of the tapered part of the outercup 38. In order to decrease the amount of residual removal fluid, the rotation speed of the substrate G is set to be greater than the initial rotation speed that allows the removal fluid to be shaken off. The operation of increasing the rotation speed of this substrate G may be performed any time such as at the same time as, after, or before the innercup 37 and the outercup 38 are lowered. In this manner, treatment fluid mainly made of rinsing fluid scattering from the substrate G hits the tapered part of the outercup 38 and/or the external wall and is then drained from the drain pipe 40b. Next, discharging the rinsing fluid is stopped, the rinsing fluid discharge nozzle 48 is stored at a predetermined position, and the rotation speed of the substrate G is further increased and then kept for a predetermined duration. In other words, spin drying for drying the substrate G is performed by rotating it at a high speed.

Next, the nozzle holding arm 41 is moved to a predetermined position in the innercup 37, and then kept there. Afterwards, the lifting mechanism 50a is extended, then only the redevelopment chemical discharge nozzle 42a is lowered and kept at a low position where a predetermined redevelopment chemical is applied onto the substrate G using the redevelopment chemical discharge nozzle 42a, thereby forming a redevelopment chemical puddle while the substrate G is being scanned. Once the redevelopment chemical puddle is formed, during a predetermined redevelopment processing time (redevelopment reaction time), the lifting mechanism 50a returns the redevelopment chemical discharge nozzle 42a to the upper position and holds it there. The nozzle holding arm 41 is retracted from the innercup 37 and the outercup 38 and the nozzle holding arm 47 is then driven instead, keeping the rinsing fluid discharge nozzle 48 at a predetermined position above the substrate G. Afterwards, the innercup 37 and the outercup 38 are lifted and then kept at an upper position (on the left side in FIG. 5).

The substrate G is then rotated at a low speed, and as the redevelopment chemical on the substrate G is about to be shaken off, the rinsing fluid discharge nozzle 48 starts discharging the rinsing fluid. At almost the same time as this operation starts, the exhaust outlet 39 starts evacuating. In other words, before the redevelopment reaction time elapses, it is preferable for the exhaust outlet 39 not to function, and thus no adverse influence such as air current development due to the operation of the exhaust outlet 39 develops on the redevelopment chemical puddle formed on the substrate G.

The redevelopment chemical and the rinsing fluid scattering towards the outer area of the substrate G after the substrate G starts rotating hit the tapered part of the innercup 37 and/or external wall (vertical side wall) and are then guided down to drain from the drain pipe 40a. After a predetermined time has elapsed since rotation of the substrate G has started, the innercup 37 and the outercup 38 are lowered and then kept at a lower position while discharging rinsing fluid and also rotating the substrate G. At the lower position, the horizontal position of the substrate G is set to be almost the same as that of the tapered part of the outercup 38. In order to decrease the amount of residual removal fluid, the rotation speed of the substrate G is set to be greater than the initial rotation speed that allows removal fluid to be shaken off. The operation of increasing the rotation speed of this substrate G may be performed any time such as at the same time as, after, or before the innercup 37 and the outercup 38 are lowered. In this manner, treatment fluid mainly made of rinsing fluid scattering from the substrate G hits the tapered part of the outercup 38 and/or the external wall and is then drained from the drain pipe 40b. Next, discharging the rinsing fluid is stopped, the rinsing fluid discharge nozzle 48 is stored at a predetermined position, and the rotation speed of the substrate G is further increased and then kept for a predetermined duration. In other words, spin drying for drying the substrate G is performed by rotating it at a high speed.

In this manner described above, successive processing by the redevelopment/remover unit (REDEV/REMV) 30 is completed. Afterwards, in the reverse order to that described above, the transfer arm 21a carries the processed substrate G out from the redevelopment/remover unit (REDEV/REMV) 30.

On the other hand, the reflow processing unit (REFLW) 60 of the processing station 2 performs reflowing by softening a resist formed on the substrate G using an organic solvent such as a thinner atmosphere and thereby re-covering.

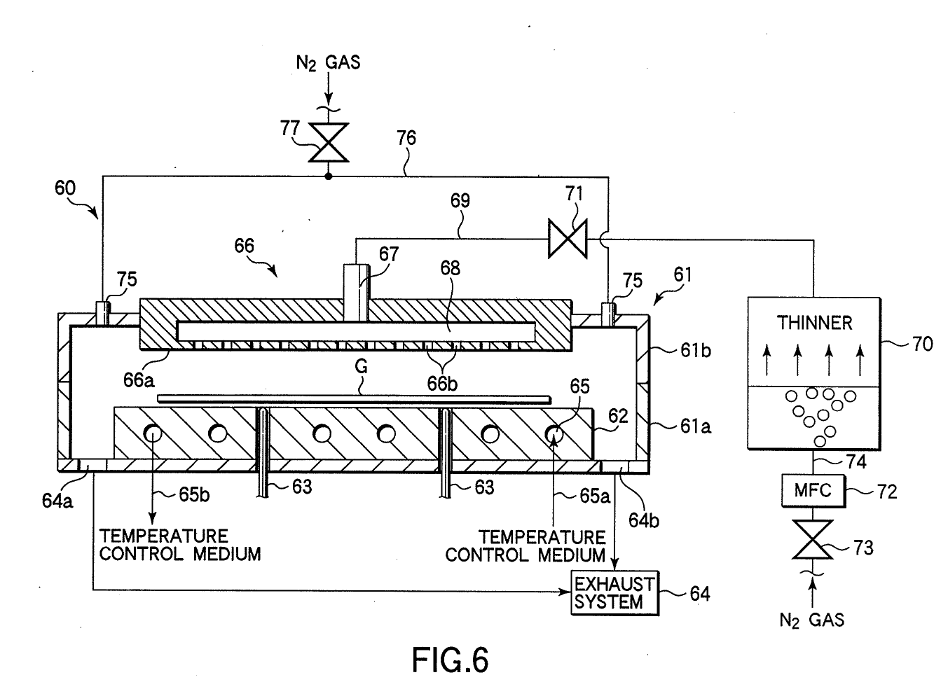

Now, the structure of the reflow processing unit (REFLW) 60 is described in detail. FIG. 6 is a cross-section of an outline of the reflow processing unit (REFLW) 60. The reflow processing unit (REFLW) 60 includes a chamber 61. The chamber 61 includes a lower chamber 61a and an upper chamber 61b connected to the upper part of the lower chamber 61a. The upper chamber 61b and the lower chamber 61a are structured to be able to open and close by an open/close mechanism not shown in the drawing; wherein the transfer unit 21 carries in/out the substrate G when it is closed.

Within this chamber 61, a supporting table 62 horizontally supporting the substrate G is provided. The supporting table 62 is made of a material such as aluminum superior in thermal conductivity.

The supporting table 62 includes three lifting pins 63 (only two are illustrated in FIG. 6), which are driven by a lifting mechanism to lower and raise the substrate G and pass through the supporting table 62. These lifting pins 63 lift the substrate G from the supporting table 62 up to a predetermined position when the substrate G is transferred between the lifting pins 63 and the transfer unit 21, and they are held so that the tips thereof are in height the same as the upper surface of the supporting table 62 while the substrate G is being subjected to ref lowing.

Exhaust outlets 64a and 64b connected to an exhaust system 64 are formed at the bottom of the lower chamber 61a. The ambient gas in the chamber 61 is evacuated through this exhaust system 64.

A temperature adjustment medium flow path 65 is provided in the supporting table 62. A temperature adjustment medium such as temperature control coolant is introduced to this temperature adjustment medium flow path 65 via a temperature adjustment medium introduction pipe 65a and then drained from the temperature adjustment medium drain pipe 65b and circulated. The heat (e.g., for cooling) is transferred via the supporting table 62 to the substrate. G, thereby controlling the temperature of the to-be-processed surface of the substrate G to be a predetermined temperature.

A shower head 66 is provided on the ceiling of the chamber 61, facing the supporting table 62. Numerous gas discharge holes 66b are formed in the undersurface 66a of this shower head 66.

A gas lead-in part 67 is provided at the upper center of the shower head 66 and coupled to a space 68 formed inside of the shower head 66. A gas supplying pipe 69 is connected to the gas lead-in part 67, and a bubbler tank 70, which supplies an organic solvent such as thinner vapor, is connected to the other end of the gas supplying pipe 69. Note that an on-off valve 71 is provided on the gas supplying pipe 69.

A N₂ gas supplying pipe 74 connected to a N₂ gas supplying source not shown in the drawing is provided as a bubble generation means to vaporize thinner at the bottom of the bubbler tank 70. A mass flow controller 72 and an on-off valve 73 are provided on the N₂ gas supplying pipe 74. The bubbler tank 70 includes a temperature adjustment mechanism not shown in the drawing, which adjusts the temperature of the thinner stored inside to a predetermined temperature. It is structured to allow introduction of N₂ gas from the N₂ gas supplying source not shown in the drawing to the bottom of the bubbler tank 70 under the control of the mass flow controller 72 that controls the flow thereof, vaporization of the thinner in the bubbler tank 70 in which the temperature is adjusted to a predetermined temperature, and introduction of the resulting gas to the chamber 61 via the gas supplying pipe 69.

Multiple purge gas lead-in parts 75 are provided at the upper rim of the shower head 66, and a purge gas supplying pipe 76, which supplies a purge gas such as N₂ gas to the chamber 61, is connected to each purge gas lead-in part 75. The purge gas supplying pipe 76 is connected to a purge gas supplying source not shown in the drawing, and an on-off valve 77 is provided therebetween.

First, in such a structure of the reflow processing unit (REFLW) 60, the upper chamber 61b is disconnected from the lower chamber 61a. In this state, the transfer arm 21a of the transfer unit 21 carries in a substrate G having a resist pattern provided through preprocessing and redevelopment, and then mounts it on the supporting table 62. The upper chamber 61b is connected to the lower chamber 61a, and the chamber 61 is then closed. Afterwards, the on-off valve 71 of the gas supplying pipe 69 and the on-off valve 73 of the N₂ gas supplying pipe 74 are opened. The N₂ gas flow is adjusted by the mass flow controller 72 and a vaporized amount of thinner is controlled. The bubbler tank 70 sends the resultant thinner vapor to the space 68 of the shower head 66 via the gas supplying pipe 69 and the gas lead-in part 67, and the vapor is then output from the gas discharge holes 66b. Consequently, the chamber 61 confines a predetermined density of thinner atmosphere.

Since a resist pattern is formed on the substrate G mounted on the supporting table 62 in the chamber 61, this resist is exposed to the thinner atmosphere, resulting in penetration of the thinner into the resist. As a result, the resist softens and its fluidity increases, and the resist deforms, covering a predetermined area (target region) of the surface of the substrate G. At this time, the temperature adjustment medium is introduced to the temperature adjustment medium flow path 65 provided in the supporting table 62, heat thereof transfers to the substrate G via the supporting table 62, and the temperature of the to-be-processed surface of the substrate G is adjusted to a predetermined temperature such as 20C. degrees. Once the gas including thinner discharged onto the surface of the substrate G from the shower head 66 hits the surface of the substrate G, it flows towards the exhaust outlets 64a and 64b and is consequently discharged out from the chamber 61.

As described above, after the reflow processing unit (REFLW) 60 has completed reflowing, the on-off valve 77 on the purge gas supplying pipe 76 is opened while continuing to discharge, and N₂ gas as a purge gas is introduced to the chamber 61 via the purge gas lead-in part 75, replacing the inner-chamber atmosphere. Afterwards, the upper chamber 61b is disconnected from the lower chamber 61a. In reverse order to that described above, the transfer arm 21a carries out the substrate G subjected to reflowing from the reflow processing unit (REFLW) 60.

Each of the three heating/cooling units (HP/COL) 80a, 80b, and 80c includes a hot plate unit (HP) for heating each substrate G and a cooling plate unit (COL) for cooling down each substrate G, which are stacked (not shown in the drawing). These heating/cooling units (HP/COL) 80a, 80b, and 80c heat and cool down the substrate G subjected to preprocessing, redevelopment processing, and ref lowing as necessary.

As shown in FIG. 3, each unit of the reflow processing system 100 is connected to process controller 90, which includes a CPU in the control unit 3. The process controller 90 has a user interface 91 connected thereto, which includes a keyboard used by a process manager to enter commands for managing the reflow processing system 100 and a display or the like for displaying a visualized operating status of the reflow processing system 100.

The process controller 90 also has a storage unit 92 connected thereto, which is stored with recipes including control programs to be executed for a variety of processes by the process controller 90 in the reflow processing unit 100 and process condition data, etc.

In conformity with a command or the like from the user interface 91, a recipe is then retrieved from the storage unit 92 as necessary and executed by the process controller 90; in other words, a desired process is performed by the reflow processing unit 100 under the control of the process controller 90. The recipes described above may be stored in computer-readable storage media such as CD-ROM, hard disk, flexible disk, or flash memory, or they may be transmitted from other apparatus via a dedicated communication line, for example.

In the reflow processing unit 100 structured as described above, first, the transfer arm 11a of the transfer unit 11 in the cassette station 1 accesses a cassette C accommodating unprocessed substrates G and retrieves a single substrate G. The substrate G is transferred from the transfer arm 11a of the transfer unit 11 down to the transfer arm 21a of the transfer unit 21 running along the central transfer path 20 in the processing station 2; this transfer unit 21 carries it into the redevelopment/remover unit (REDEV/REMV) 30. Afterwards, once the redevelopment/remover unit (REDEV/REMV) 30 has performed preprocessing and redevelopment processing, the substrate G is retrieved from the redevelopment/remover unit (REDEV/REMV) 30 by the transfer unit 21, and then carried to one of the heating/cooling units (HP/COL) 80a, 80b, and 80c. The substrate G subjected to the predetermined heating and cooling in each of the heating/cooling units (HP/COL) 80a, 80b, and 80c is carried to the reflow processing unit (REFLW) 60, which then performs ref lowing. After the reflowing is completed, predetermined heating and cooling is performed by each of the heating/cooling units (HP/COL) 80a, 80b, and 80c as necessary. The substrate G gone through such successive processing is transferred down to the transfer unit 11 of the cassette station 1 by the transfer unit 21.

Next, a principle of the reflow method used in the reflow processing unit (REFLW) 60 is described.

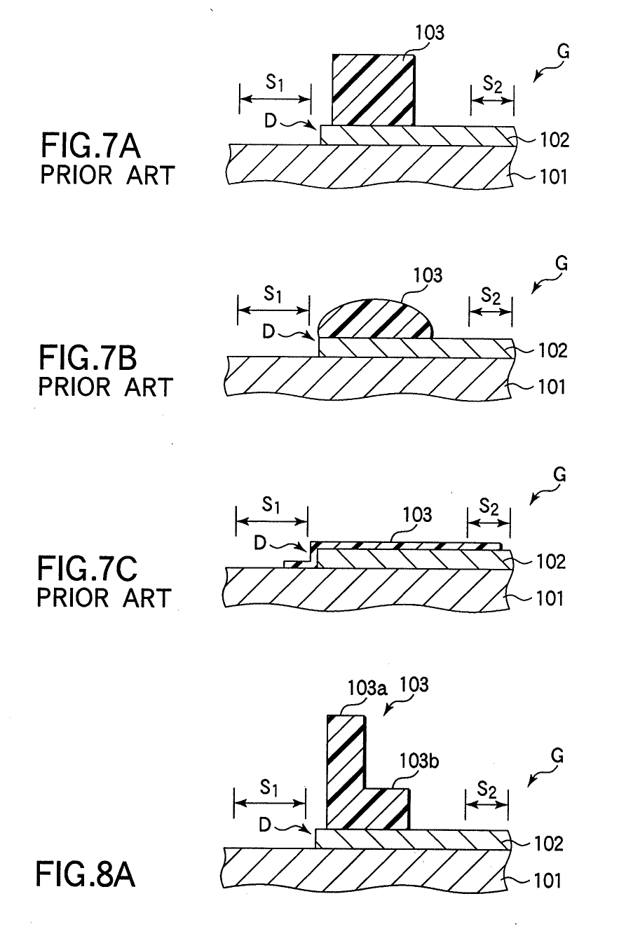

FIG. 7A shows a simplified cross-section of a resist 103 formed around the surface of a substrate G, explaining a conventional reflow method. The shape of the resist 103 surface is flat herein. An underlying layer 101 and an underlying layer 102 are stacked on the substrate G. Further on the resulting surface, the patterned resist 103 is formed.

According to the example of FIG. 7A, target region S₁ exists on the surface of the underlying layer 101. Softened resist 103 flows to this target region S₁ and covers it. On the other hand, prohibiting region S₂ such as an etching region exists on the surface of the underlying layer 102, wherein this underlying layer 102 must avoid being covered by the resist 103. The end of the underlying layer 102 protrudes laterally towards the target region S₁ rather than the side of the resist 103, and a step D is formed therebetween. Such a step D is formed by redeveloping the resist 103 and thereby shaving the resist 103 laterally.

In the state shown in FIG. 7A, an organic solvent such as thinner is made to touch and penetrate into the resist to soften and deform the resist 103 as shown in FIG. 7B. Since the softened resist 103 increases in fluidity, it spreads across the surface of the underlying layer 102. However, since it cannot go over the step D until the thickness of the flowing resist 103 exceeds a fixed height, the moving speed of the resist 103 gets slower at the stage D where the resist 103 stops moving ahead.

Due to such stoppage at around this step D, the resist 103 moves in the opposite direction to the step D where it is easy to flow. In other words, most of it tends to move towards a prohibiting region S₂ where coverage with the resist should be avoided. As shown in FIG. 7C, the resist 103 does not cover the target region S₁ sufficiently, but reaches the prohibiting region S₂ and covers the surface thereof. When coverage of the target region S₁ is not complete such that the resist 103 reaches the prohibiting region S₂ where coverage with the resist is not desired, precision of the etched shape formed using, for example, the reflowed resist 103 decreases, resulting in failures in devices such as TFTs and decrease in yield. The state of the resist 103 described with reference to FIGS. 7A through 7C emanates from not being able to control the flow direction of the resist 103 softened by, the organic solvent.

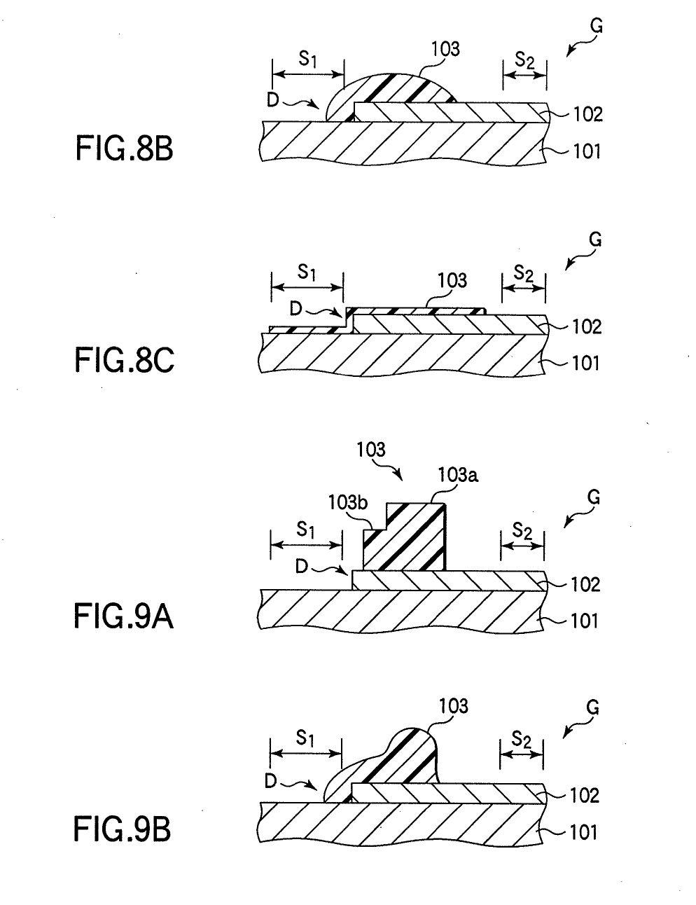

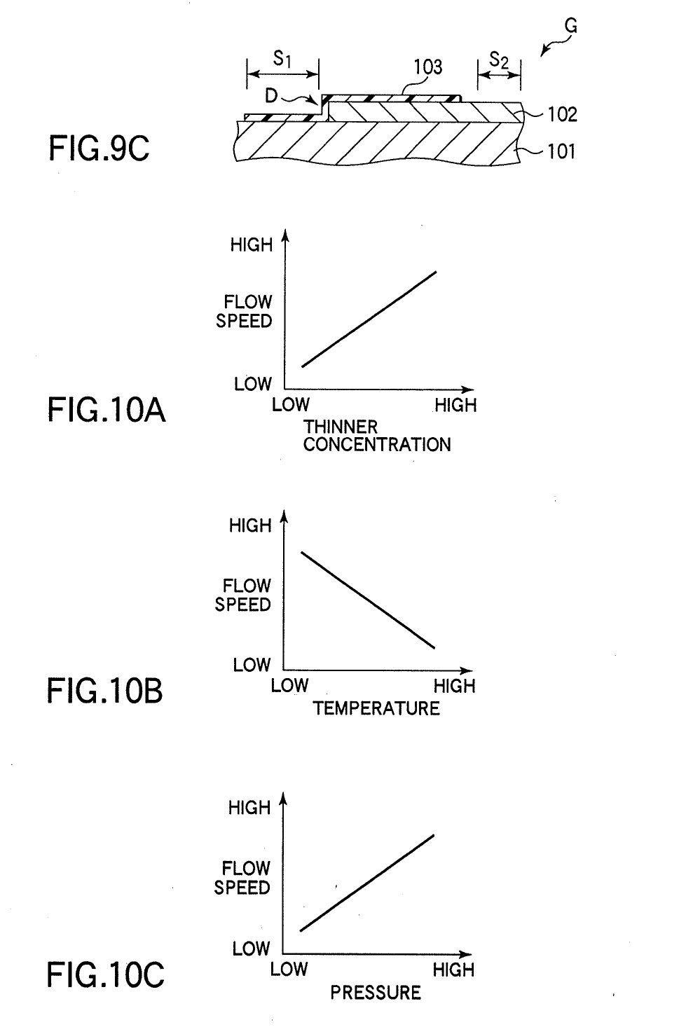

FIGS. 8A through 8C and 9A through 9C describe an idea of the reflow method according to the present invention.

FIG. 8A shows a simplified cross-section of the resist 103 formed around the surface of the substrate G. The target region S₁, the prohibiting region S₂ and the structure where an underlying layer 101 and an underlying layer 102 are stacked and formed, thereupon the patterned resist 103 is then formed, and the step D is formed at the end of the underlying layer 102, are the same as those shown in FIG. 7A.

The resist 103 according to the present invention has parts differing in thickness, and a step on the surface. In other words, there are different regions in height on the surface of the resist 103, having a thick region 103a and a thin region 103b thinner than this thick region 103a. The thick region 103a is formed on the target region S₁ side while the thin region 103b is formed on the prohibiting region S₂ side.

In the state shown in FIG. 8A, an organic solvent such as thinner is made to touch the resist to soften and deform the resist 103. The softened resist 103 increases in fluidity, spreading across the surface of the underlying layer 102. As described above, since the resist 103 includes the thick region 103a and the thin region 103b, the flow orientation for the softened resist 103 can be controlled. Since the thick region 103a, for example, has a large exposed area to the thinner atmosphere, the thinner penetrates easily, resulting in a faster softening speed and high fluidity. Furthermore, since the thick region 103a has a relatively fast softening speed and has a large volume, the stagnant period until it goes over the step D is shortened, making it easier for the resist 103 to reach the target region S₁, as shown in FIG. 8.

On the other hand, the thin region 103b has a smaller exposed area to the thinner atmosphere than the thick region 103a, thus softening speed thereof is not fast and fluidity does not increase as much as the thick region 103a. Furthermore, the thin region 103b has a slower softening speed and a smaller volume than the thick region 103a, and thus flow of the resist 103 towards the prohibiting region S₂ is controlled, and as shown in FIG. 8C, deformation stops without reaching the prohibiting region S₂. This allows secure etching precision using the reflowed resist 103 as a mask, and favorable device characteristics.

In this manner, use of the resist 103 having the thick region 103a, the thin region 103b, and different regions in height on the surface allows control of the flow direction in which the resist 103 spreads, and secure sufficient etching precision.

FIGS. 9A through 9C show simplified cross-sections of a resist 103 formed near the surface of a substrate G of another example.

As shown in FIG. 9A, the target region S₁, the prohibiting region S₂, and the structure where an underlying layer 101 and an underlying layer 102 are stacked and formed, thereupon the patterned resist 103 is then formed, and the step D is formed at the end of the underlying layers 10 and 102, are the same as those shown in FIGS. 7A and 8A. The resist 103 according to this example has different regions in height on the surface, the thick region 103a, and the thin region 103b relatively thinner than the thick region 103a. However, in this example, the positional relationship of the thick region 103a and the thin region 103b relative to the target region S₁ and the prohibiting region S₂ is reverse to that in FIG. 8A, wherein the thin region 103b is formed on the target region S₁ side and the thick region 103a is formed on the prohibiting region S₂ side.

In the state shown in FIG. 9A, an organic solvent such as thinner is made to touch the resist 103 to soften and be deformed. The softened resist 103 increases in fluidity, spreading across the surface of the underlying layer 102. As described above, since the resist 103 includes the thick region 103a and the thin region 103b, the flow direction of the softened resist 103 can be controlled. The thick region 103a, for example, has a large exposed area to the thinner atmosphere; however the lateral width (thickness)) is also formed to be thick. Therefore, it takes a long time for the thinner to penetrate into the center of the thick region 103a when the thinner concentration in the atmosphere is weak, and as shown in FIG. 9B, and the entire thick region 103a never softens immediately nor becomes a ref lowed state. Accordingly, in a state where the inside of the thick region 103a does not soften, the thick region 103a acts as a dam, controlling the flow of the softened resist 103 towards the prohibiting region S₂.

The thin region 103b has a smaller exposed area to the thinner atmosphere than the thick region 103a, however the entire volume is also small. Therefore, the thinner permeates quickly into the center even when the thinner concentration in the atmosphere is weak, softening relatively quickly. Furthermore, a reaction against the flow of the softened resist 103 towards the prohibiting region S₂ controlled by the thick region 103a acting as a dam is that the flow towards the target region S₁ increases and that the stagnant period until it goes over the step D is shortened, making it easier for the resist 103 to reach the target region S₁.

In this manner, as a result of it taking a long time to soften up to the center of the thick region 103a due to a slower softening speed than the thin region 103b, the flow of the softened resist 103 stops without reaching the prohibiting region S₂. This allows secure etching precision using the reflowed resist 103 as a mask, and favorable device characteristics.

In this manner, use of the resist 103 having the thick region 103a, the thin region 103b, and different regions in height on the surface allows control of the flow direction in which the resist 103 spreads, and secure sufficient etching precision.

The control of the resist flow orientation shown in FIGS. 8A through 8C and 9A through 9C may seem conflicting at first glance. However, the reflowed state of the resist 103 changes in conformity with conditions such as thinner concentration, flow rate, temperature of the substrate G (supporting table 62), inner pressure of the chamber 61 during ref lowing by the reflow processing unit (REFLW) 60, for example.

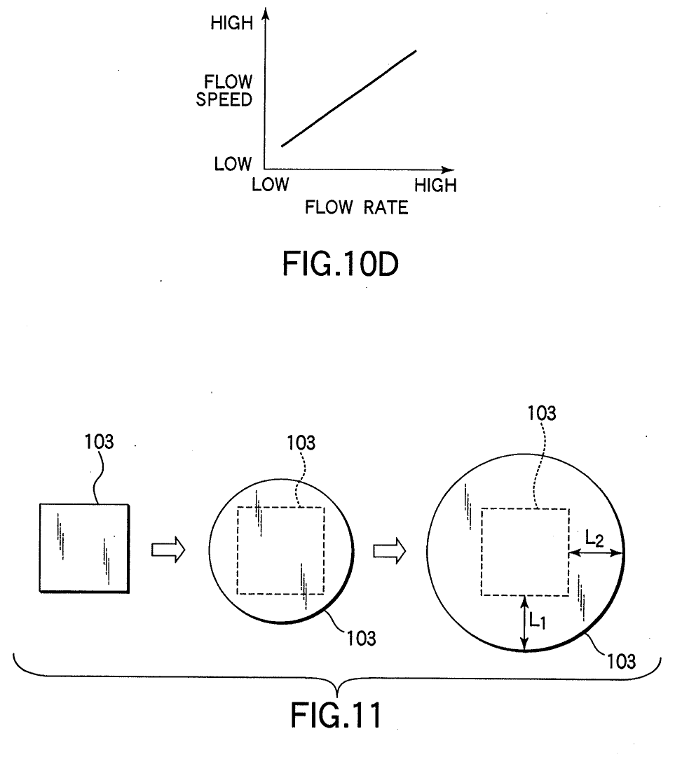

As shown in FIGS. 10A through 10D, for example, while thinner concentration, flow rate, and chamber inner pressure increase and flow speed of the resist also increases, flow speed of the resist 103 tends to decrease as the temperature increases. In other words, even if the form and location of the thick region 103a and the thin region 103b were the same, the degree of softening of the resist would change due to the thinner concentration within the chamber 61, for example, and behaviors such as flow orientation and flow speed would be different. Accordingly, use of the resist 103 having different regions in height (the thick region and the thin region) on the surface allows control of its flow orientation and coverage area as needed under determined and selected experimental optimum conditions such as combined conditions of organic solvent concentration, flow rate, substrate temperature and pressure during ref lowing.

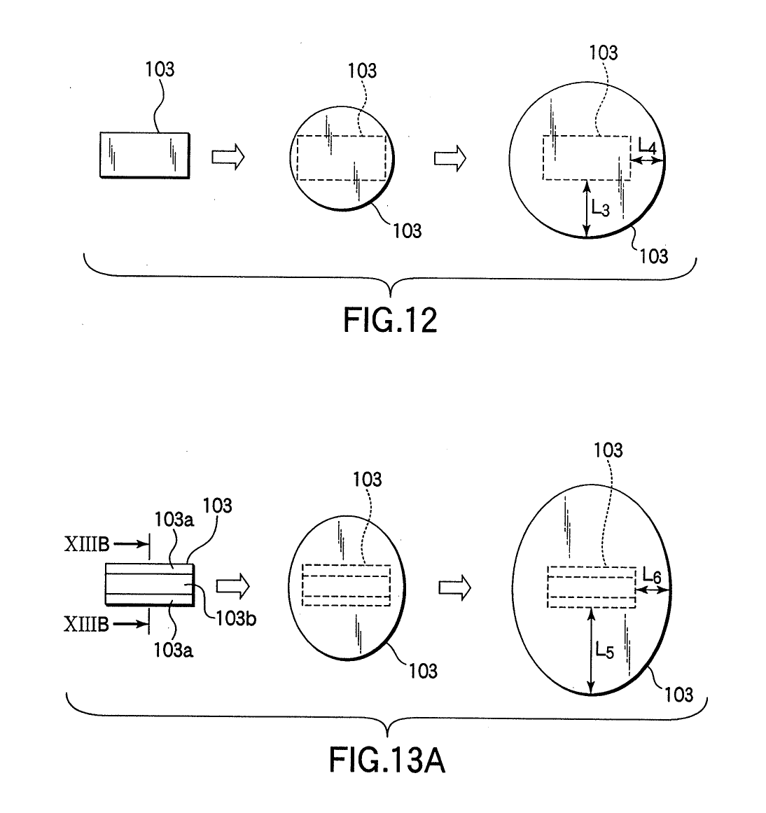

FIGS. 11 and 12 are top views of main parts on a substrate G surface describing yet another example. In this example, by designing a resist 103 having a flat shape instead of having different regions in height (the thick region and the thin region) on the surface as shown in FIGS. 8A and 9A as already described, control of the flow orientation thereof as needed is attempted. Note that a state of the resist 103 before subjected to ref lowing is shown on the left side of FIGS. 11 and 12 while the state of the resist 103 during ref lowing is shown in the center, and the state of the ref lowed resist 103 is shown on the right side.

FIG. 11 shows how the deformed resist 103 resulting from subjecting an original square resist 103 when seen from above to reflowing spreads. From FIG. 11, it can be seen that the resist 103 spreads in an approximate circle centered on the original resist 103 (square) indicated by a dotted line. On the other hand, FIG. 12 shows how the resist 103 resulting from subjecting an original rectangle resist 103 to reflowing to dissolve itself spreads. It can be seen also in this case that the resist 103 spreads in an approximate circle centered on the original resist 103 (rectangle) indicated by a dotted line.

As shown in these FIGS. 11 and 12, regardless of the flat shape of the original resist 103, the softened resist 103 has a characteristic of spreading in an approximate circle due to surface tension as a characteristic of the reflowing. Use of this characteristic of how this resist 103 spreads allows control of the flow orientation thereof. More specifically, we can see that L₁ is almost equal to L₂, but L₃ is a larger flow distance than L₄, through comparison of distances L₁ and L₂ from the reflowed original resist 103 of FIG. 11 with flow distances L₃ and L₄ from the reflowed original resist 103 of FIG. 12. In other words, a difference in the flow distances L₃ and L₄ can be provided by using a flat quadrilateral resist 103 and adjusting the horizontal and vertical dimensions thereof. In this manner, the flow orientation and the flow distance (coverage area) of the softened resist 102 can be controlled by devising the flat shape of the resist 105.

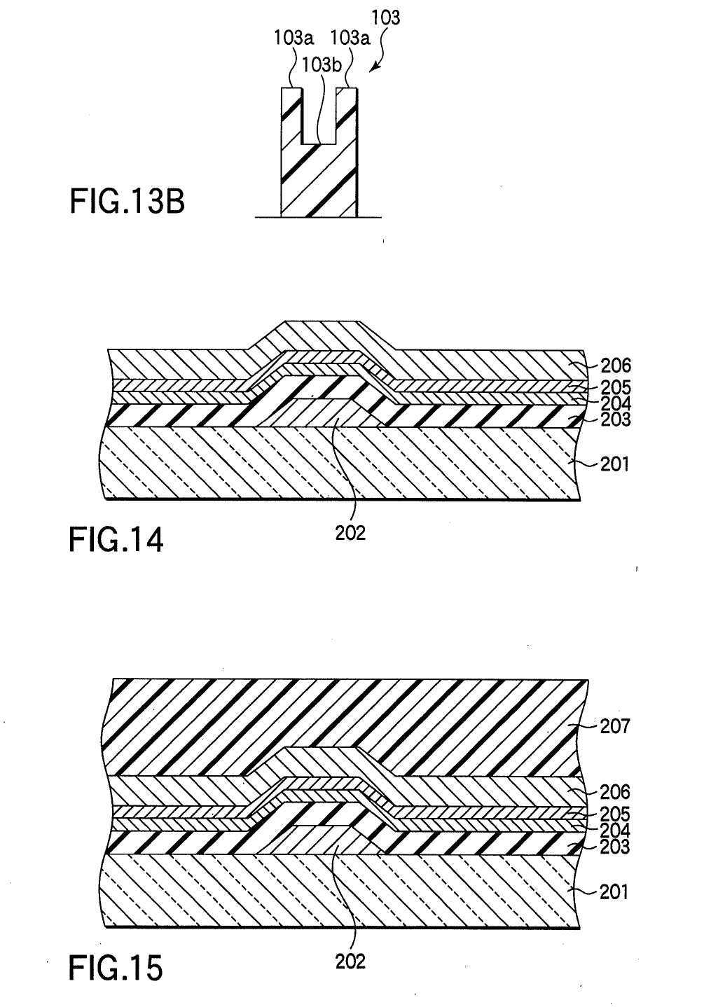

For example, as shown in FIG. 13A, a rectangle resist 103 (see the cross section of FIG. 13B) having thick regions 103a and a thin region 103b deployed therebetween along the length thereof is prepared. When the resist 103 shown in FIG. 13A is subjected to reflowing, a flow distance L₅ of the resist 103 extending vertically in this drawing is greater than a flow distance L₆ of the resist 103 extending along the width of this drawing because the resist has a rectangular shape. Furthermore, since the resist 103 having the thick regions 103a along the length is used, the flow distance L₅ further increases, resulting in an oval re-coverage area by the resist 103 when viewed from above. In this manner, combination of such a plane shape and such a cross sectional shape of the resist 103 allows further effective control of the flow orientation and the flow distance (coverage area) of the resist 103.

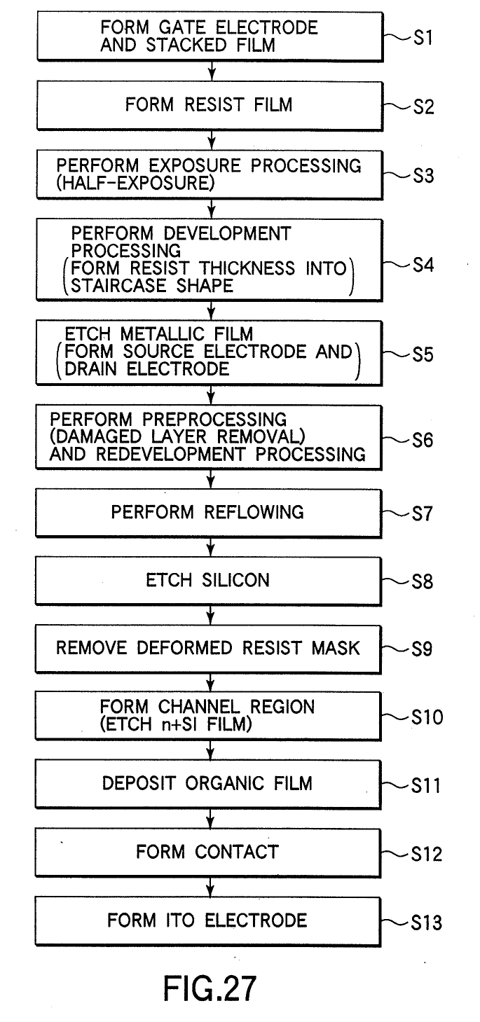

Next, an embodiment where the reflow method according to the present invention is applied to a fabrication process for a TFT for an LCD is described while referencing FIGS. 14 through 26. Note that the main processes are also shown in a flowchart of FIG. 27.

First, as shown in FIG. 14, a gate electrode 202 and a gate line not shown in the drawing are formed on an insulating substrate 201 made of a transparent substrate such as glass, and a gate insulating film 203 such as a silicon nitride film, an amorphous silicon (a−Si) film 204, an n+Si film 205 to be used as an ohmic layer, and a metallic film 206 for electrodes are stacked and deposited in this order (Step S1).

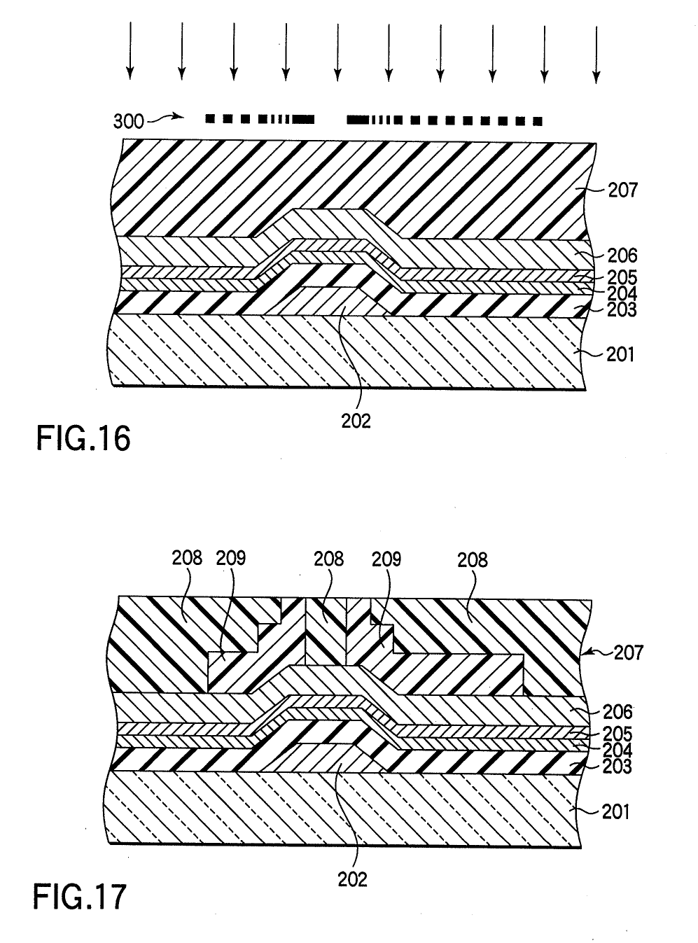

Next, as shown in FIG. 15, a resist 207 is formed on the metallic film 206 for electrodes (Step S2). As shown in FIG. 16, exposure processing is then performed using a half-tone mask 300 as an exposure mask, which have regions different from each other in transmissivity of light and is capable of varying light exposure for respective regions of the resist 207 (Step S3). This half-tone mask 300 may be structured to provide three different exposures for the resist 207. Performing half-exposure on the resist 207 in this manner results in formation of exposed resist regions 208 and unexposed resist regions 209, as shown in FIG. 17. The unexposed resist regions 209 are formed into a staircase shape at the borders with the exposed resist regions 208 due to the transmissivity of the mask 300.

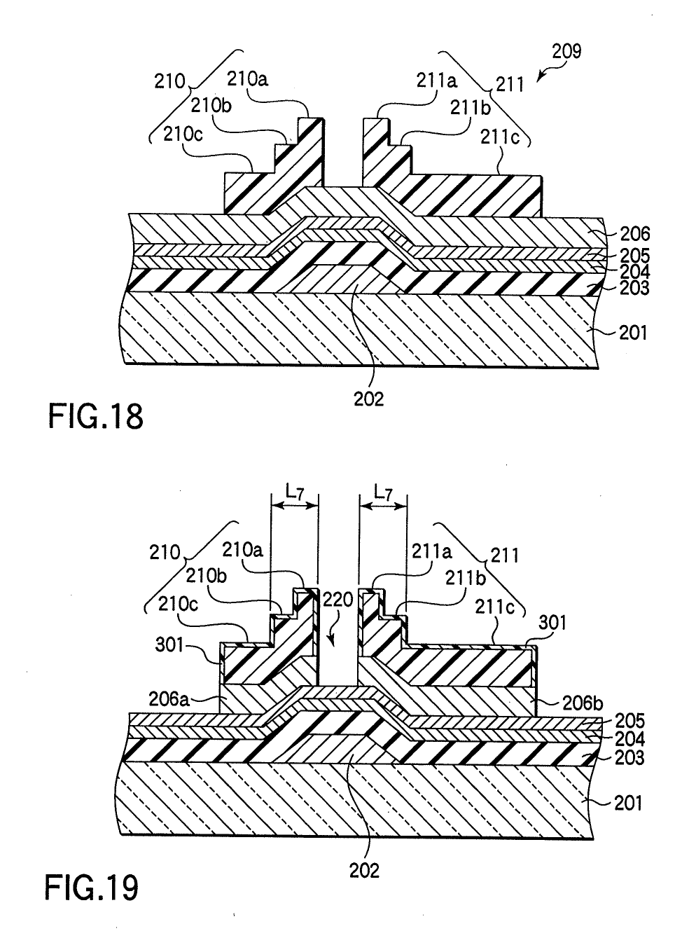

Development is performed after exposure, thereby removing the exposed resist regions 208, leaving the unexposed resist regions 209 on the metallic film 206 for electrodes, as shown in FIG. 18 (Step S4). The unexposed resist regions 209 are separated into a resist mask 210 for source electrodes and a resist mask 211 for drain electrodes, configuring a pattern. The resist mask 210 for source electrodes includes a first thick region 210a, a second thick region 210b, and a third thick region 210c in order of thickness formed in a staircase shape through half-exposure. The resist mask 211 for drain electrodes includes a first thick region 211a, a second thick region 211b, and a third thick region 211c in order of thickness formed in a staircase shape through half-exposure.

Afterwards, the metallic film 206 for electrodes is etched using the remaining unexposed resist regions 209 as an etching mask, and as shown in FIG. 19, a concave portion 220, which will become a channel region later, is formed (Step S5). As a result of this etching, a source electrode 206a and a drain electrode 206b may be formed to expose the surface of the n+Si film 205 within the concave portion 220 between the electrodes. Furthermore, thin surface damaged layers 301 are formed through etching near the surfaces of the resist mask 210 for source electrodes and the resist mask 211 for drain electrodes.

Next, wet processing is performed using a removal fluid, the surface damaged layers 301 are removed (preprocessing) after the metallic film 206 for electrodes are etched, and redevelopment processing is then performed for partially removing the unexposed resist regions 209 on the source electrode 206a and the drain electrode 206b (Step S6). This preprocessing and redevelopment processing may be continuously performed by the redevelopment/remover unit (REDEV/REMV) 30 of the reflow processing system 100.

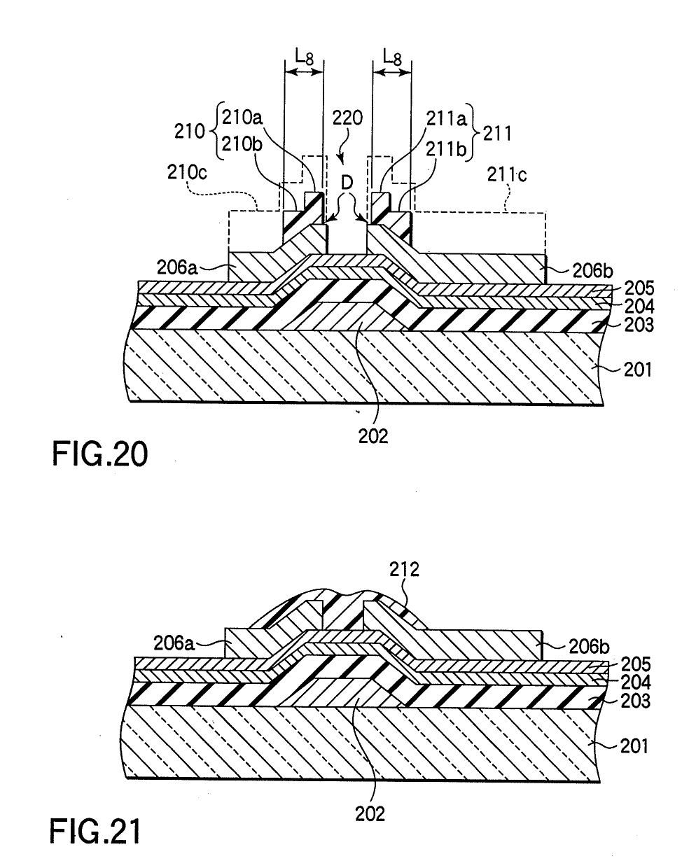

Through this redevelopment processing, the coverage areas by the resist mask 210 for source electrodes and the resist mask 211 for drain electrodes are considerably reduced, as shown in FIG. 20. More specifically, of the resist mask 210 for source electrodes, the third thick region 210c is completely removed, and the first thick region 210a and the second thick region 210b are left on the source electrode 206a. Furthermore, even of the resist mask 211 for drain electrodes, the third thick region 211c is completely removed, and the first thick region 211a and the second thick region 211b are left on the drain electrode 206b.

In this manner, the coverage areas by the resist mask 210 for source electrodes and the resist mask 211 for drain electrodes are reduced through redevelopment processing, thereby preventing the deformed ref lowed resist from protruding out from the end of the source electrode 206a or the end of the drain electrode 206b that are on opposite sides of a target region (concave portion 220) and covering underlayers. As a result, miniaturization of TFTs is possible.

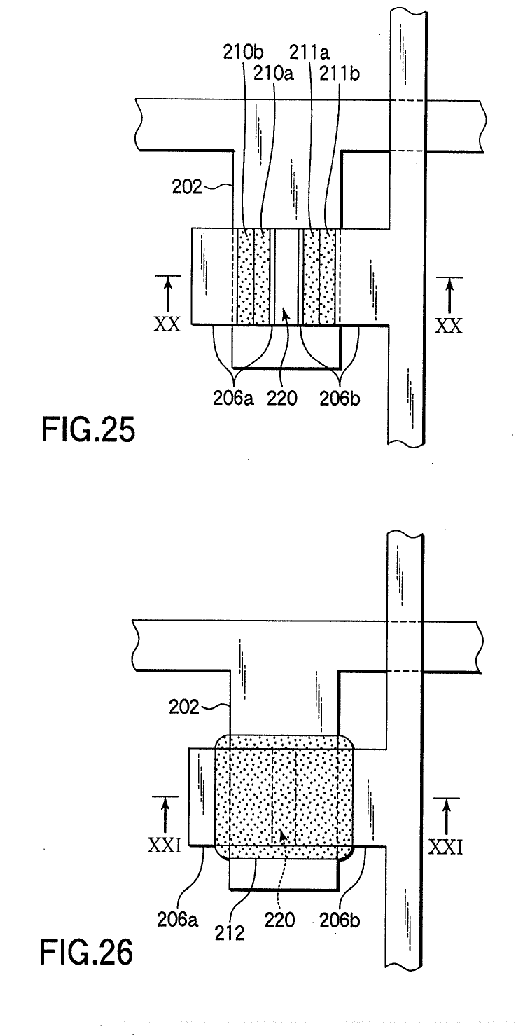

Note that in FIG. 20, contours of the resist mask 210 for source electrodes and the resist mask 211 for drain electrodes before redevelopment processing are indicated by dotted lines for comparison. The top view corresponding to the cross-section shown in FIG. 20 is shown in FIG. 25.

Furthermore, thicknesses of the first thick region 210a and the second thick region 210b (or the first thick region 211a and the second thick region 211b), and total lateral thicknesses (widths) L₈ become smaller than total lateral thicknesses (widths) L₇ (see FIG. 19) before redevelopment through redevelopment processing. A step D is then formed in the concave part 220 due to misalignment of the edge of the first thick region 210a of the resist mask 210 for source electrodes in the concave part 220 from the edge of the source electrode 206a directly therebelow. Similarly, a step D is formed in the concave part 220 due to misalignment of the edge of the first thick region 211a of the resist mask 211 for drain electrodes in the concave part 220 from the edge of the source electrode 206b directly therebelow.

In other words, as a result of the resist mask 210 for source electrodes and the resist mask 211 for drain electrodes also shaved laterally through redevelopment, the distance between the end of the resist mask 210 for source electrodes in the concave part 220 and the end of the resist mask 211 for drain electrodes is greater than distance between the source electrode 206a and the drain electrode 206b in the layer therebelow.

When such steps D are formed, not only does control of the flow orientation of the softened resist when covering the target region (in this case, the concave part 220) with the softened resist in the subsequent reflow process become difficult, but it also causes increase in ref lowing time and decrease in throughput since the flow stops until it goes over the steps D.

Therefore, with this embodiment, the first thick regions 210a and 211a as thick regions and the second thick regions 210b and 211b as thin regions are provided to the resist mask 210 for source electrodes and the resist mask 211 for drain electrodes, respectively, and control of the flow orientation of the softened resist and shortening of the processing time are implemented, so as for the softened resist to easily go over the steps D and flow into the concave part 220 of the target region. In the ref lowing (Step S7), the resist softened by an organic solvent such as thinner is then made to flow into the concave part 220, which is intended to become a channel region later, in a short time, and thus the concave part 220 may be securely covered. This reflowing is performed by the reflow processing unit (REFLW) 60 of FIG. 6.

FIG. 21 shows the periphery of the concave part 220 being covered by a deformed resist 212. The top view corresponding to the cross-section shown in FIG. 21 is shown in FIG. 26.

With the conventional technology, there is a problem that since the deformed resist 212 spreads up to the other side of the concave part 220 of the source electrode 206a and the drain electrode 206b, for example, and covers the n+Si film 205, which is an ohmic contact layer, the covered parts are not etched in the following silicon etching process, and etching precision is lost, thereby bringing about TFT failure and reduction in yield. Furthermore, there is a problem that if the coverage area by the deformed resist 212 is largely estimated beforehand and then designed, necessary area (dot area) for fabricating a single TFT increases, and high integration and miniaturization of TFTs is difficult.

On the contrary, with this embodiment, since reflowing is performed after drastically reducing the volume of the resist mask 210 for source electrodes and the resist mask 211 for drain electrodes through redevelopment processing, the covered region by the deformed resist 212 is limited to the periphery of the concave part 220, which is the target region for reflowing, and the thickness of the deformed resist 212 is formed thin. This allows high integration and miniaturization of TFTs.

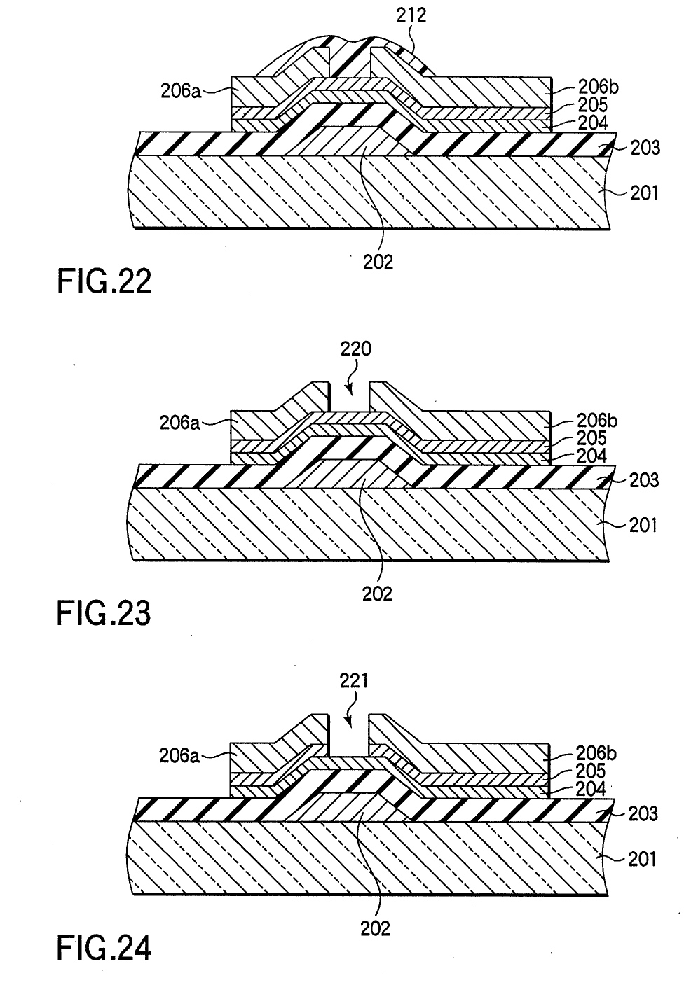

Next, as shown in FIG. 22, the n+Si film 205 and the a−Si film 204 are etched using the source electrode 206a, the drain electrode 206b and the deformed resist 212 as an etching mask (Step S8). Afterwards, as shown in FIG. 23, the deformed resist 212 is removed through wet processing or other related processing, for example (Step S9). The n+Si film 205 exposed in the concave part 220 is then etched using the source electrode 206a and the drain electrode 206b as an etching mask (Step S10). As a result, a channel region 221 is formed, as shown in FIG. 24.

While subsequent processes have been omitted from the drawings, an organic film is formed so as to cover the channel region 221, the source electrode 206a, and the drain electrode 206b (Step S11), a contact hole connected to the source electrode 206a (drain electrode 206b) is formed through photolithography and etching (Step S12), and a transparent electrode made of indium-tin oxide (ITO) or the like is then formed (Step S13). As a result, a TFT for an LCD is fabricated.

As is comprehensible from the description of this embodiment given above, according to the present invention, use of a resist film having thick regions and thin regions for ref lowing allows control of the flow orientation and flow area (spreading area) of softened resist. Therefore, use of the reflow method according to the present invention for fabrication of semiconductor devices such as TFTs having an etching process repeatedly conducted using a resist as a mask allows omission of masks and reduction in number of processes. Accordingly, it is possible to achieve reduction in processing time and improvement in etching precision, and contribute to high integration and miniaturization of semiconductor devices.

Note that the present invention is not limited to the above-given embodiment, and various modifications are possible within the scope of the present invention. For example, the example of TFT fabrication using a glass substrate for an LCD is given in the above-given description; however, the present invention may also be applied to ref lowing for a resist formed on a substrate such as another flat panel display (FPD) substrate or a semiconductor substrate. Furthermore, while the resist film is structured including thick films and thin films in the above-given embodiment, change in resist thickness is not limited to two levels and may have three or more levels. Moreover, not only can the resist thickness be varied to be a staircase shape, but it may be formed to have a slanted surface such that the thickness gradually varies. In this case, a slanted surface may be formed on the resist surface after half-exposure by giving a slant to the applied film thickness of the resist in advance.

1-31. (canceled)

32. A method for forming a pattern of a semiconductor device, the method comprising:
preparing a process object including a reservation region with a reflow-target region and a reflow-prohibition region respectively present on opposite sides thereof, the process object including first and second films laminated from below in this order on its surface and covering the reservation region, the reflow-target region, and the reflow-prohibition region;
forming a resist film to cover the second film over the reservation region, the reflow-target region, and the reflow-prohibition region;
patterning the resist film to form a first resist mask by subjecting the resist film to light exposure using a half-tone mask, the first resist mask having regions different from each other in transmissivity of light, as a light-exposure mask, and then developing the first resist mask, such that the first resist mask includes first, second, and third portions arrayed stepwise on the reservation region in this order from a side adjacent to the reflow-target region to a side adjacent to the reflow-prohibition, and the first portion has a thickness larger than the second portion while the second portion has a thickness larger than the third portion;
etching the second film from above the first resist mask used as an etching mask to form a patterned second film by removing portions of the second film on the reflow-target region and the reflow-prohibition region while saving a portion of the second film on the reservation region;
performing re-development that decreases the first resist mask in thickness overall until the third portion of the first resist mask disappears to transform the first resist mask to a second resist mask, such that the second resist mask includes fourth and fifth portions derived from the first and second portions of the first resist mask and arrayed stepwise on the reservation region in this order from a side adjacent to the reflow-target region, the fourth portion has a thickness larger than the fifth portion, and the second resist mask exposes a portion of the patterned second film corresponding to the third portion of the first resist mask because of removal of the third portion;
performing a reflowing treatment that softens and fluidizes the second resist mask on the patterned second film to transform the second resist mask to a deformed resist film, such that the deformed resist film covers a portion of the first film on the reflow-target region and still exposes a portion of the first film on the reflow-prohibition region without reaching there; and
etching the first film from above the deformed resist film and then patterned second film both used as an etching mask to form a patterned first film by removing a portion of the first film on the reflow-prohibition while maintaining portions of the first film on the reservation region and the reflow-target region.

33. The method according to claim 32, wherein the first, second, and third portions of the first resist mask correspond to portions of the resist film unexposed to light in said step of subjecting the resist film to light exposure using the half-tone mask.

34. The method according to claim 32, wherein the reflowing treatment comprises placing the process object in an atmosphere of an organic solvent and fluidizing the second resist film by the organic solvent penetrating thereinto.

35. The method according to claim 32, wherein, between said etching the second film and said performing re-development, the method further comprises removing damaged surface layers of the first resist mask.

36. The method according to claim 32, wherein the fourth portion of the second resist mask is set back from an end of the patterned second film adjacent to the reflow-target region due to said removing surface damaged layers and said performing re-development.

37. The method according to claim 32, wherein the process object includes a support substrate, a gate electrode disposed on the support substrate, and an insulating film covering the gate electrode, along with a semiconductor film, an ohmic-contact film, and a metal film laminated on the insulating film in this order, and the first and second films are the ohmic film and the metal film, respectively.

38. The method according to claim 37, wherein the method further comprises etching the semiconductor film together with the ohmic-contact film serving as the first film in said etching the first film.

39. The method according to claim 38, wherein, after said etching the first film, the method further comprises:
removing the deformed resist film; and
then, etching the patterned first film from above the patterned second film used as an etching mask by removing a portion of the patterned first film on the reflow-target region while maintaining a portion of the patterned first film on the reservation region.

40. The method according to claim 32, wherein the second film includes an inclined upper surface inclined downward from a side adjacent to the reflow-target region, and the fourth and fifth portions of the second resist mask are disposed on the inclined upper surface.
